(19) United States
(12) Patent Application Publication
(10) Pub. No.: US 2013/0265053 A1
(43) Pub. Date: Oct. 10, 2013

(54) MAGNETIC RESONANCE IMAGING APPARATUS, AND IMAGING PARAMETER OPTIMIZING METHOD

(71) Applicants: Hiroyuki Itagaki, Tokyo (JP); Takashi Nishihara, Tokyo (JP)

(72) Inventors: Hiroyuki Itagaki, Tokyo (JP); Takashi Nishihara, Tokyo (JP)

(73) Assignee: HITACHI MEDICAL CORPORATION, TOKYO (JP)

(21) Appl. No.: 13/991,190

(22) PCT Filed: Nov. 30, 2011
(86) PCT No.: PCT/JP2011/077597

§ 371 Date: Jun. 3, 2013

(30) Foreign Application Priority Data
Dec. 16, 2010 (JP) 2010-280783

(51) Int. Cl. G01R 33/54

(52) U.S. Cl. CPC G01R 33/543
USPC 324/309

(57) ABSTRACT

Disclosed is a technique which allows easy optimization of imaging conditions in imaging using two-dimensional excitation as a pre-pulse. To this end, a parameter which specifies the excitation region of the two-dimensional excitation is shifted, a value (optimum value) when a predefined index is ideal for each application to be applied is decided in a subsequent main imaging sequence, and the optimum value is set to the value of the parameter, whereby optimization is performed. A two-dimensional excitation pre-pulse which is excited under optimum excitation conditions is used to optimize the parameter in the main imaging sequence.

### TECHNICAL FIELD

The present invention relates to an imaging technique using a magnetic resonance imaging (hereinafter, referred to as MRI) apparatus. In particular, the present invention relates to a technique which allows optimization of imaging conditions using two-dimensional excitation exciting an imaging target in a cylindrical shape or a prismatic shape.

### BACKGROUND ART

Two-dimensional excitation is primarily used as a pre-pulse. The pre-pulse is executed earlier than an imaging (hereinafter, referred to as main imaging) sequence in which a diagnostic image is acquired, and suppresses an artifact or enhances signal intensity of a specific imaging target, such as blood, in addition to monitoring body motion.

As a representative application example of the two-dimensional excitation, there are a diaphragm navigator (for example, see NPL 1) which monitors a respiratory cycle, a non-contrast magnetic resonance angiography (MRA) (for example, see PTL 1) which images a blood vessel and a blood flow without using a contrast medium, and the like.

### CITATION LIST

### Patent Literature

PTL 1: Japanese Patent No. 4316078

### Non Patent Literature

NPL 1: Revised Edition “Getting a Perfect Command of MRI”, page 96, edited by Junichi Hachiya, published by Medical View Co., Ltd.

### SUMMARY OF INVENTION

### Technical Problem

The two-dimensional excitation which is used as the pre-pulse has a limited excitation region compared to general planar excitation, and thus a subsequent diagnostic image hardly undergoes deterioration in image quality. Meanwhile, since the excitation region is narrow, it is necessary to excite the two-dimensional excitation at an accurate position according to the purpose of execution. In a present situation, since an operator manually sets the excitation region, variation occurs in setting precision.

In the main imaging sequence, setting precision of various parameters (imaging conditions) related to the excitation region is important. In particular, in the non-contrast MRA, it is important to accurately obtain the blood flow rate, the inversion time TI, and the travel distance of blood for a predetermined time in advance. In a present situation, while the entire imaging target or a part of the imaging target is excited in a planar shape to measure the blood flow rate or TI, since a part other than blood is excited, it is difficult to accurately obtain the blood flow rate, TI, and the travel distance of a measurement target.

The invention has been accomplished in consideration of the above situation, and an object of the invention is to provide a technique which allows easy optimization of imaging conditions in imaging using two-dimensional excitation as a pre-pulse.

### Solution to Problem

In the invention, a parameter which specifies the excitation region of two-dimensional excitation is shifted, a value (optimum value) when a predefined index is ideal for each application to be applied is decided in a subsequent main imaging sequence, and the optimum value is set to the value of the parameter, whereby optimization is performed. A two-dimensional excitation pre-pulse which is excited under optimum excitation conditions is used to optimize the parameter in the main imaging sequence.

Specifically, the invention provides a magnetic resonance imaging apparatus including an imaging unit which images a desired region of an inspection target arranged in a static magnetic field by nuclear magnetic resonance, and a control unit which controls the imaging unit in accordance with a predefined imaging sequence and performs an arithmetic process. The control unit includes an excitation condition optimization unit which optimizes excitation conditions of a two-dimensional excitation sequence exciting an imaging space in a cylindrical shape, an elliptic cylindrical shape, or a prismatic shape, and the imaging unit performs the two-dimensional excitation sequence under the excitation conditions optimized by the excitation condition optimization unit.

The invention provides an imaging parameter optimizing method in a magnetic resonance imaging apparatus including an excitation condition optimization step of optimizing excitation conditions of a two-dimensional excitation sequence exciting an imaging space in a cylindrical shape, an elliptic cylindrical shape, or a prismatic shape in accordance with an application to be applied.

### Advantageous Effects of Invention

According to the invention, it is possible to easily optimize imaging conditions in imaging using two-dimensional excitation as a pre-pulse.

### BRIEF DESCRIPTION OF DRAWINGS

FIG. 1 is a block diagram showing the overall configuration of an MRI apparatus according to an embodiment of the invention.

FIG. 2 is a functional block diagram of a control processing system according to the embodiment of the invention.

FIG. 3(a) is an explanatory view illustrating a two-dimensional excitation region, and FIG. 3(b) is an explanatory view illustrating a two-dimensional excitation sequence.

FIG. 4 is an explanatory view illustrating a shift condition setting screen according to the embodiment of the invention.

FIG. 5 is a flowchart of a two-dimensional excitation condition optimization process according to the embodiment of the invention.

FIG. 6(a) is an explanatory view illustrating a two-dimensional excitation position in a diaphragm navigator, and FIG. 6(b) is an explanatory view illustrating a respiratory monitor waveform generated from a navigation echo signal to be acquired by a diaphragm navigator.

FIG. 7 is a flowchart of an optimization process according to the embodiment of the invention when an application to be applied is a diaphragm navigator.

FIG. 8(a) is a graph of a respiratory monitor waveform according to the embodiment of the invention, and FIG. 8(b) is an explanatory view illustrating another optimization process according to the embodiment of the invention.

FIG. 9 is a flowchart of another example of an optimization process according to the embodiment of the invention when an application to be applied is a diaphragm navigator.

FIG. 10 is an explanatory view illustrating the effects of a two-dimensional excitation optimization process of the invention, and in particular, FIG. 10(a) shows an image and a respiratory monitor waveform before application and FIG. 10(b) shows an image and a respiratory monitor waveform after application.

FIG. 11 is a flowchart of an optimization process according to the embodiment of the invention when an application to be applied is a non-contrast MRA.

FIG. 12 is a sequence diagram of an optimization process according to the embodiment of the invention when an application to be applied is a diaphragm navigator.

FIG. 13(a) is an explanatory view illustrating an imaging position in a non-contrast MRA, and FIG. 13(b) is an explanatory view illustrating a sequence of a non-contrast MRA and behavior of nuclear magnetization.

FIGS. 14(a) and 14(b) are sequence diagrams which are executed by an imaging condition optimization unit according to the embodiment of the invention.

FIG. 15 is an explanatory view illustrating the flow of processing when a respiratory monitor using a diaphragm navigator and a non-contrast MRA are combined.

### DESCRIPTION OF EMBODIMENTS

Hereinafter, an embodiment to which the invention is applied will be described. In this embodiment, a parameter of two-dimensional excitation for use in a pre-pulse is optimized in accordance with a subsequent main imaging sequence. Hereinafter, in all the drawings for describing the embodiment of the invention, parts having the same functions are represented by the same reference signs, and repetitive description will be omitted.

First, an MRI apparatus of this embodiment will be described. The MRI apparatus images the upper side relating to the space distribution of density of nuclear species to be imaged in an object or the space distribution of a relaxation time of an excited state, whereby the form or function of the object is imaged in a two-dimensional or three-dimensional manner. At present, as the nuclear species to be imaged of the MRI apparatus, a hydrogen nucleus (proton) which is a principal constitutive substance of the object is in widespread clinical use.

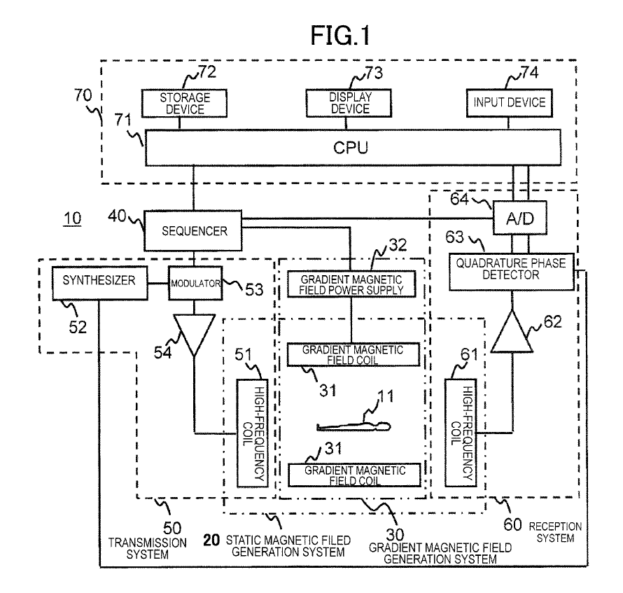

FIG. 1 is a block diagram showing the overall configuration of an MRI apparatus 10 of this embodiment. The MRI apparatus 10 of this embodiment obtains a tomographic image of an object 11 using a magnetic resonance phenomenon, and as shown in FIG. 1, includes a static magnetic field generation system 20, a gradient magnetic field generation system 30, a transmission system 50, a reception system 60, a control processing system 70, and a sequencer 40.

The static magnetic field generation system 20 generates a uniform static magnetic field in a direction perpendicular to the body axis in a space around the object 11 in the case of a vertical magnetic field system or in a direction of the body axis in the case of a horizontal magnetic field system, and has a permanent magnet-type, normal conducting, or superconducting static magnetic field generation source arranged around the object 11.

The gradient magnetic field generation system 30 includes gradient magnetic field coils 31 which are wound in the three axis directions of x, y, and z as the coordinate system (stationary coordinate system) of the MRI apparatus 10, and a gradient magnetic field power supply 32 which drives the gradient magnetic field coils. The gradient magnetic field generation system 30 drives the gradient magnetic field power supply 32 of the gradient magnetic field coils 31 in accordance with a command from the sequencer 40 described below, thereby applying gradient magnetic fields Gx, Gy, and Gz in the three axis directions of x, y, and z.

The transmission system 50 irradiates a high-frequency magnetic field pulse (hereinafter, referred to as “RF pulse”) onto the object 11 so as to induce nuclear magnetic resonance in the spins of the atoms forming a biological tissue of the object 11. The transmission system 50 includes a high-frequency oscillator (synthesizer) 52, a modulator 53, a high-frequency amplifier 54, and a transmission-side high-frequency coil (transmission coil) 51. The high-frequency oscillator 52 generates an RF pulse and outputs the RF pulse at the timing according to a command from the sequencer 40. The modulator 53 amplitude-modulates the output RF pulse, and the high-frequency amplifier 54 amplifies the amplitude-modulated RF pulse and supplies the RF pulse to the transmission coil 51 arranged near the object 11. The transmission coil 51 irradiates the supplied RF pulse onto the object 11.

The reception system 60 detects a nuclear magnetic resonance signal (echo signal or NMR signal) which is emitted by the nuclear magnetic resonance in the spins of the atoms forming the biological tissue of the object 11. The reception system 60 includes a reception-side high-frequency coil (reception coil) 61, a signal amplifier 62, a quadrature phase detector 63, and an A/D converter 64. The reception coil 61 is arranged near the object 11 and detects an NMR signal of a response of the object 11 induced by electromagnetic waves irradiated from the transmission coil 51. The detected NMR signal is amplified by the signal amplifier 62, is divided into orthogonal signals of two systems by the quadrature phase detector 63 at the timing according to a command from the sequencer 40. Each signal is converted to a digital quantity by the A/D converter 64, and the digital quantity is sent to the control processing system 70.

The sequencer 40 repeatedly applies an RF pulse and a gradient magnetic field pulse in accordance with a predetermined pulse sequence. The pulse sequence describes a high-frequency magnetic field, a gradient magnetic field, and the timing or intensity of signal reception, and is stored in the control processing system 70 in advance. The sequencer 40 operates in accordance with an instruction from the control processing system 70, and transmits various command required for data collection of a tomographic image of the object 11 to the transmission system 50, the gradient magnetic field generation system 30, and the reception system 60.

The control processing system 70 controls the entire MRI apparatus 10, processes various kinds of data, and displays and stores the processing result. The control processing system 70 includes a CPU 71, a storage device 72, a display device 73, and an input device 74. The storage device 72 has a hard disk and an external storage device, such as an optical disc or a magnetic disk. The display device 73 is a display device, such as a CRT or liquid crystal. The input device 74 is an interface which inputs various kinds of control information of the MRI apparatus 10 or control information of a process to be performed by the control processing system 70, and includes, for example, a track ball or a mouse, and a keyboard. The input device 74 is arranged near the display device 73. An operator inputs instructions and data required for various processes of the MRI apparatus 10 interactively through the input device 74 while viewing the display device 73.

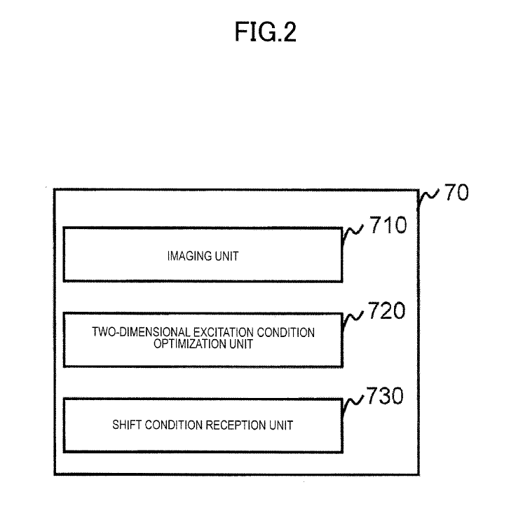

The CPU 71 executes a program stored in advance in the storage device 72 in accordance with an instruction input by the operator, and controls the operation of the MRI apparatus 10 or realizes each process of the control processing system 70, such as various kinds of data processing. FIG. 2 is a functional block diagram illustrating each function which is realized when the CPU 71 executes a program in the control processing system 70 of this embodiment.

As described above, the control processing system 70 of this embodiment includes an imaging unit 710 which controls the respective units of the MRI apparatus 10 and realizes imaging of a desired region of the object 11, a two-dimensional excitation condition optimization unit 720 which optimizes excitation conditions of two-dimensional excitation, and a shift condition reception unit 730 which receives conditions for optimization.

The excitation conditions for optimization include, for example, the position L, diameter φ, slope θ, flip angle FA, and the like of the excitation region (two-dimensional excitation region) of the two-dimensional excitation. The two-dimensional excitation region is a cylindrical, elliptic cylindrical, or prismatic region, and the position L is the coordinates in a predefined coordinate system centering on the center axis of the two-dimensional excitation region. The slope θ is the angle between the direction of the static magnetic field and the center axis of the excitation region. In the case of an elliptic cylindrical shape, the diameter φ is the average value of the major axis and the minor axis of the elliptical cross-section, and in the case of a prismatic shape, the diameter φ is the diameter of a circumscribed cylindrical shape or an inscribed cylindrical shape.

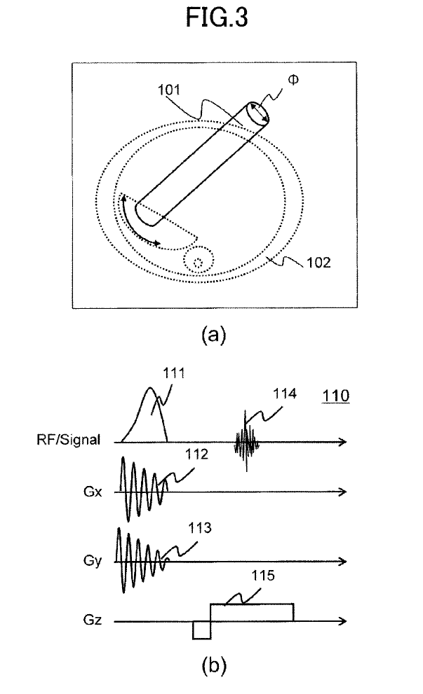

Prior to describing the two-dimensional excitation condition optimization unit 720 and the shift condition reception unit 730, a region which is excited by two-dimensional excitation and a pulse sequence which realizes two-dimensional excitation will be described referring to FIG. 3. FIG. 3(a) is an explanatory view illustrating a region (two-dimensional excitation region) 101 which is excited by two-dimensional excitation. Here, a case where the shape of the two-dimensional excitation region 101 is a cylindrical shape is illustrated. FIG. 3(b) shows a pulse sequence (two-dimensional excitation sequence) 110 of two-dimensional excitation. In this drawing, RF/Signal, Gx, Gy, and Gz respectively denote an RF pulse and an echo signal, and the axes of a gradient magnetic field in the x-axis direction, a gradient magnetic field in the y-axis direction, and a gradient magnetic field of the z-axis direction. The same applies to each pulse sequence diagram in this specification.

The two-dimensional excitation sequence 110 includes a two-dimensional exciting RF pulse 111, a vibration gradient magnetic field (Gx) 112 in the x-axis direction, and a vibration gradient magnetic field (Gy) 113 in the y-axis direction. In the two-dimensional excitation sequence 110, the two-dimensional exciting RF pulse 111 is applied with the vibration gradient magnetic field (Gx) 112 in the x-axis direction and the vibration gradient magnetic field (Gy) 113 in the y-axis direction. Accordingly, the cylindrical region (two-dimensional excitation region) 101 having an axis parallel to the z axis shown in FIG. 3(a) is selectively excited.

An echo signal 114 which is obtained from the excited region is sampled in time series while giving a lead-out gradient magnetic field 115 in a predetermined axis direction and arranged in a k space. Here, for example, a case where the echo signal 114 is acquired while giving a lead-out gradient magnetic field (Gz) 115 in the z-axis direction is illustrated.

The two-dimensional excitation region 101 is specified by parameters, such as the position L, diameter φ, slope θ, flip angle FA, and the like with respect to an imaging target 102. The parameters which specify the two-dimensional excitation region 101 are referred to as two-dimensional excitation conditions. These two-dimensional excitation conditions are defined by specifying the waveforms of the two-dimensional exciting RE pulse 111 and vibration gradient magnetic fields 112 and 113 of the two-dimensional excitation sequence 110. Hereinafter, in this embodiment, as the two-dimensional excitation conditions, for example, the settings of the position L, diameter φ, slope θ, and the flip angle FA with respect to the imaging target 102 will be described.

In the related art, an operator inputs the two-dimensional excitation region 101 on a positioning image acquired in advance, and visually decides the optimum position L, diameter φ, and slope θ. The flip angle FA is generally designated using a UI (User Interface) for parameter input.

That is, if an image including the imaging target 102 shown in FIG. 3(a) is a positioning image, the two-dimensional excitation region 101 is displayed on the display device 73 as a UI, the operator operates the UI using the input device 74 to adjust the two-dimensional excitation region 101. The CPU 71 of the control processing system 70 decides the waveforms of the RF pulse 111 and the vibration gradient magnetic fields 112 and 113 of the two-dimensional excitation sequence 110 on the basis of the two-dimensional excitation region 101 decided by the operator on the positioning image.

In this embodiment, the two-dimensional excitation conditions, such as the position L, diameter φ, slope θ, the flip angle FA, and the like of the two-dimensional excitation region 101 input by the operator, are optimized by the two-dimensional excitation condition optimization unit 720 in accordance with an application to be applied.

The two-dimensional excitation condition optimization unit 720 repeats a monitor scan while changing each of the position L, diameter φ, slope (angle) θ, and flip angle PA of the two-dimensional excitation region 101 from an initial value by a predefined shift amount a predefined number of times, and decides an optimum value, whereby optimization is performed. The initial value is set by the operator on the positioning image and the UI for parameter input. This process which is executed by the two-dimensional excitation condition optimization unit 720 is referred to as a two-dimensional excitation condition optimization process. The monitor scan is defined in advance by an application to be applied. The monitor scan is executed in accordance with an application to be applied along with a predefined algorithm. From the result of the monitor scan, a value which conforms to a predefined index is decided as an optimum value in accordance with an application to be applied along with a predefined algorithm. The monitor scan, the algorithm, and the conditions are stored in the storage device 72 in association with an application to be applied.

The shift condition reception unit 730 receives a two-dimensional excitation condition to be adjusted, an application type to be applied, and adjustment conditions. The adjustment conditions include, for example, an amount (shift amount) of change of a two-dimensional excitation condition to be adjusted and a count (shift count).

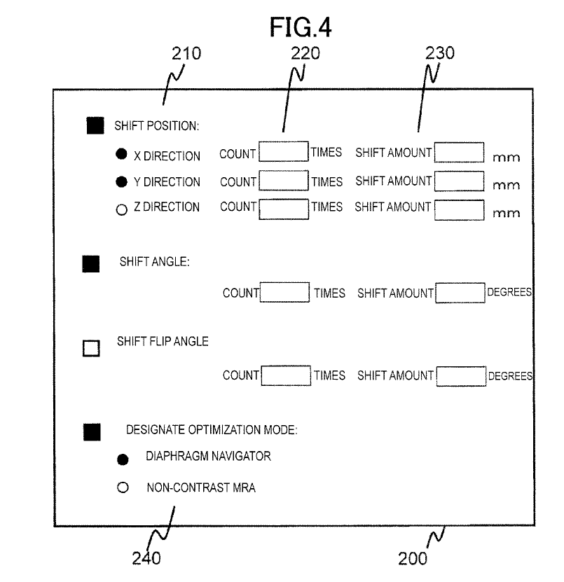

A shift condition setting screen 200 which is generated by the shift condition reception unit 730 so as to receive an input of each piece of information from the operator and displayed on the display device 73 will be described referring to FIG. 4. Here, for example, a case the position L, slope (angle) 0, and the flip angle FA of the two-dimensional excitation region are displayed is shown. It is assumed that the position L can be set in each of the x direction, the y direction, and the z direction.

As shown in this drawing, shift condition setting screen 200 includes an adjustment-target designation button 210 which receives the setting of each two-dimensional excitation condition to be adjusted, a shift count input region 220 which receives the designation of a count of changes, and a shift amount input region 230 which receives the designation of a shift amount. An optimization mode setting region 240 which designates an application to be applied is further provided.

In a typical setting example of the shift conditions of the position L, for example, the shift count in each of the left-right direction and the up-down direction centering on an initial position L designated by the operator is five, the shift amount is the diameter φ, and the like.

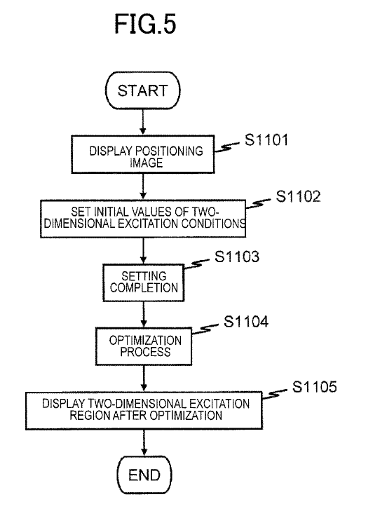

Next, the details of the two-dimensional excitation condition optimization process by the two-dimensional excitation condition optimization unit 720 of this embodiment will be described referring to FIG. 5. Here, it is assumed that the shift conditions are set in advance using the shift condition setting screen 200.

If an instruction to start the two-dimensional excitation condition optimization process is received, the two-dimensional excitation condition optimization unit 720 displays a positioning image on the display device 73 (Step S1101). The operator inputs a two-dimensional excitation region on the positioning image as in the related art. If the operator inputs the two-dimensional excitation region, the two-dimensional excitation condition optimization unit 720 reads the position L, diameter φ, and slope θ of the two-dimensional excitation region from the input two-dimensional excitation region, and stores the read values as the initial values (position L₀, diameter φ₀, and slope θ₀) of the two-dimensional excitation conditions (Step S1102).

If an instruction of initial value setting completion is received from the operator (Step S1103), the two-dimensional excitation condition optimization unit 720 performs an optimization process (Step S1104). The instruction of initial value setting completion is received by pressing of a decision button or the like which is displayed on the display device 73 with the positioning image.

In the optimization process of Step S1104, in regard to a parameter designated as an adjustment target through the adjustment target designation button 210 on the shift condition setting screen 200 from among the two-dimensional excitation conditions, the designated shift amount and the designated shift count are changed, and a monitor scan of an application to be applied is executed each time the shift amount and the shift count are changed. This is repeated, and an optimumvalue which is a parameter when a predefined index is ideal for each application to be applied is decided.

The two-dimensional excitation condition optimization unit 720 displays a region, which is specified by the position L, diameter φ, and slope θ of the two-dimensional excitation region decided by the optimization process, on the positioning image as two-dimensional excitation region after optimization, decides the waveforms of the RF pulse 111 and the vibration gradient magnetic fields 112 and 113 which realize the two-dimensional excitation conditions (Step S1105), and ends the process.

For example, the flow of the optimization process of Step S1104 when an application to be applied is a diaphragm navigator will be described. This process is executed by the two-dimensional excitation condition optimization unit 720 along with an algorithm stored in advance in the storage device 72.

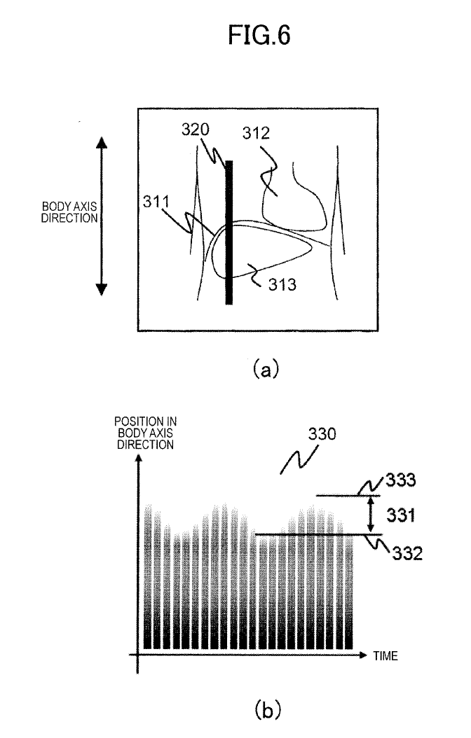

First, the feature of the diaphragm navigator will be described. FIG. 6(a) shows a two-dimensional excitation position in a general diaphragm navigator. The diaphragm navigator is a technique which monitors position fluctuation of diaphragm 311, heart 312, and liver rim 313 corresponding to a respiratory cycle. For this reason, it is important to define a region with large position fluctuation according to respiration as a two-dimensional excitation region 320. Accordingly, an echo signal (navigation echo signal) is acquired over a plurality of respiratory periods (for example, 15 seconds), and a two-dimensional excitation condition when the range (hereinafter, referred to as amplitude) of fluctuation is maximal is determined to be an optimum value.

FIG. 6(b) shows a graph in which a navigation echo signal acquired by a diaphragm navigator is arranged. Hereinafter, this graph is referred to as a respiratory monitor waveform 330. In the respiratory monitor waveform, the vertical axis represents the position coordinates in the body axis direction, and the horizontal axis represents the time. In this drawing, shading expresses signal intensity. That is, darker shading represents a higher signal.

The diaphragm navigator acquires a navigation echo signal at a predetermined time interval (for example, at every 500 ms). The acquired navigation echo signal is subjected to a one-dimensional Fourier transform, and an arrangement according to the acquisition time is created, whereby the respiratory monitor waveform 330 shown in FIG. 6(b) is obtained. Amplitude 331 of the navigation echo signal is obtained by the difference between a lower limit 332 and an upper limit 333 at a data point where signal intensity becomes a predetermined value.

In a subsequent respiratory monitor waveform, data points where signal intensity becomes a predetermined value are in data obtained by one-dimensional Fourier transform of the navigation echo signal shown in FIG. 6(b) connected by a solid line. The solid line which connects the data points corresponds to, for example, time displacement of the position of the end of the liver.

When an application to be applied is the diaphragm navigator, the two-dimensional excitation condition optimization unit 720 of this embodiment uses the diaphragm navigator to acquire echo signals in a plurality of predefined respiratory periods each time the two-dimensional excitation condition is changed, generates a respiratory monitor waveform from the obtained echo signals, and sets a two-dimensional excitation condition, in which amplitude is maximal, to an optimum value.

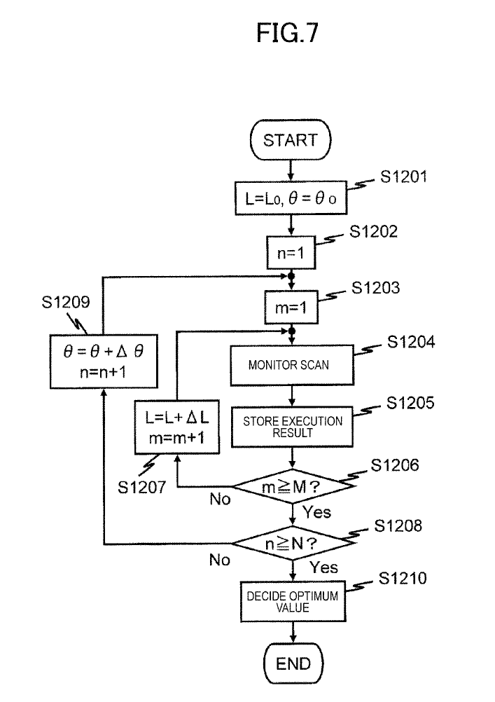

The optimization process of Step S1109 by the two-dimensional excitation condition optimization unit 720 of this embodiment which realizes the above will be described referring to FIG. 7. Here, for example, a case where parameters to be shifted are the position L (one direction) and the slope θ, and designation is made so as to change the position L (initial position L₀) by a shift amount ΔL M times and the slope θ (initial value θ₀) by a shift amount Δθ N times will be described. m and n are counters. Here, M and N are integers equal to or greater than 1, and m and n are integers which satisfy 1≦m≦M and 1≦n≦N.

The position L and the slope θ are set to the initial values (L₀ and θ₀) (Step S1201), and the counter n is set to 1 (Step S1202). The counter m is set to 1 (Step S1203). The monitor scan is executed under the two-dimensional excitation conditions which are obtained from the position L and the slope θ at this time (Step S1204). Here, as described above, as the monitor scan, a sequence which acquires echo signals (navigation echo signals) between a plurality of respiratory cycles is executed.

The execution result of the monitor scan is stored in the storage device 72 in association with the excitation conditions (position L and slope θ) during the execution (Step S1205). Thereafter, it is determined whether or not the position L is shifted M times using the counter m (Step S1206).

If m<M, the position L is shifted only by ΔL, and m is incremented by 1 (Step S1207). Then, the process returns to Step S1204, and the monitor scan is repeated.

In Step S1206, if m M, it is determined whether or not the slope θ is shifted N times using the counter n (Step S1208). If n<N, the slope θ is shifted only by Δθ, and n is incremented by 1 (Step S1209). Then, the process returns to Step S1203, and the monitor scan is repeated.

In Step S1208, if n N, the monitor scan results stored with the respective excitation conditions are compared, an optimum excitation condition (optimum value) is decided (Step S1210), and the process ends.

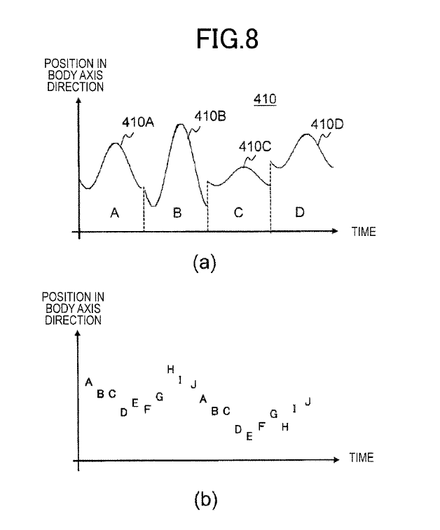

The decision method of Step S1210 when an application to be applied is a diaphragm navigator will be described. FIG. 8(a) shows a graph 410 of a respiratory monitor waveform of the result stored in Step S1205. In this graph, respective regions A, B, C, and D are data which are obtained by performing a one-dimensional Fourier transform on the navigation echo signal acquired under different two-dimensional excitation conditions (respectively referred to as excitation condition A, excitation condition B, excitation condition C, and excitation condition D) in the optimization process. The regions A, B, C, and D are respectively represented by graphs 410A, 4108, 410C, and 410D. The reason that the graphs are discontinuous between the regions is because the excitation conditions of the two-dimensional excitation are changed to change the excitation position, and position fluctuation by respiration is discontinuous.

When an application to be applied is a diaphragm navigator, an excitation condition in which amplitude of a respiratory monitor waveform is maximal is an optimum excitation condition. Accordingly, in the Step S1210 of the optimization process, the two-dimensional excitation condition optimization unit 720 compares the maximum values, the minimum values, and the ranges (hereinafter, referred to as amplitude) of fluctuation as the difference between the maximum value and the minimum value in the waveforms acquired under the respective excitation conditions. As a result, an excitation condition in which the range of fluctuation is maximal is determined to be optimal. For example, in FIG. 8(a), the regions A, B, C, and D are compared in terms of amplitude. Since the amplitude of the region B is maximal, the two-dimensional excitation condition B at this time is determined to be an optimum excitation condition (optimum value). Although it is preferable that the process for obtaining the optimum value is carried out by the two-dimensional excitation condition optimization unit 720, a user may designate a desired graph. In this case, the two-dimensional excitation condition optimization unit 720 displays the graph shown in FIG. 8(a) on the display device 73, receives a designation from the user, and sets the designation to an optimum value.

Here, although the parameters to be shifted are the position L (one direction) and the slope θ, the invention is not limited thereto. The number of loops of the above-described process may be changed in accordance with the number of parameters to be shifted.

In this embodiment, the monitor scan is executed during a period in which amplitude can be discriminated (in the above description, for 15 seconds), the result is graphically displayed, and an excitation condition with maximum amplitude is decided to be an optimum value. However, the flow of the optimization process is not limited thereto. A single navigation echo signal may be acquired as the monitor scan, all two-dimensional excitation conditions may be repeatedly executed, and an excitation condition in which maximum amplitude is obtained may be decided. That is, a single navigation echo signal is acquired under the same two-dimensional excitation conditions, and this is done for all two-dimensional excitation conditions. The above-described process is repeated a predefined number of times, a respiratory monitor waveform is generated, and a two-dimensional excitation condition in which the range of fluctuation between navigation echoes acquired under the same conditions is set to an optimum value.

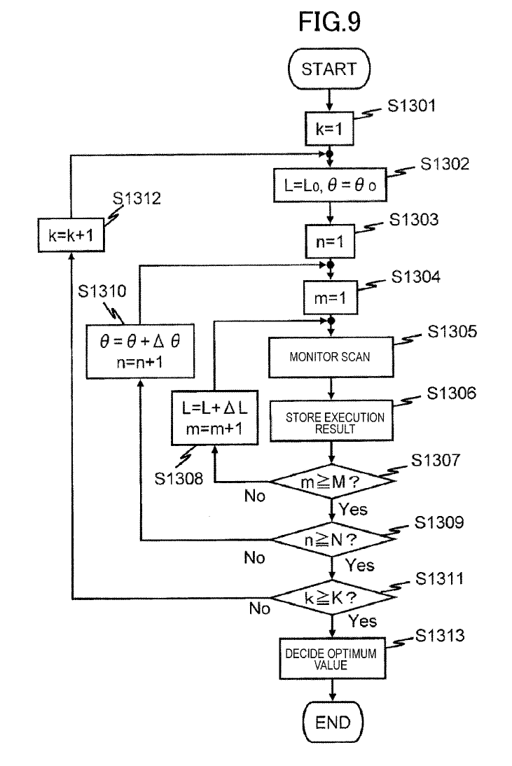

Hereinafter, the flow of the process in this case will be described referring to FIGS. 9 and 8(b). Here, it is assumed that the number of repetitions of the execution of all two-dimensional excitation conditions is K. It is assumed that K is an integer equal to or greater than 1. k which satisfies 1≦k≦K is used in a counter.

The counter k is set to 1 (Step S1301). The position L and the slope θ are set to the initial values (L₀ and θ₀) (Step S1302), and the counter n is set to 1 (Step S1303). The counter m is set to 1 (Step S1304). Then, the monitor scan is executed under the two-dimensional excitation conditions which are obtained from the position L and the slope θ at this time (Step S1305). Here, a single echo signal (navigation echo signal) is acquired as the monitor scan.

The monitor scan execution result is stored in the storage device 72 in association with the excitation conditions (position L and slope θ) during the execution (Step S1306). Thereafter, it is determined whether or not the position L is shifted M times using the counter m (Step S1307).

If m<M, the position L is shifted by ΔL, and m is incremented by 1 (Step S1308). Then, the process returns to Step S1305, and the monitor scan is repeated.

In Step S1307, if m≧M, it is determined whether or not the slope θ is shifted N times using the counter n (Step S1309). If n<N, the slope θ is shifted by Δθ, and n is incremented by 1 (Step S1310). Then, the process returns to Step S1304, and the monitor scan is repeated.

In Step S1309, if n≧N, it is determined whether or not all two-dimensional excitation conditions are changed K times using the counter k (Step S1311). If k<K, k is incremented by 1 (Step S1312), the process returns to Step S1302, and the process ends. If k≧K, the monitor scan results stored with the respective excitation conditions are compared, an optimum excitation condition (optimum value) is decided (Step S1313), and the process ends.

For example, FIG. 8(b) shows a graph 420 of a result when all two-dimensional excitation conditions are repeated twice, and the position is shifted twice, and the slope is shifted five times. Here, since the position is shifted twice and the slope is shifted five times, navigation echo signals are acquired under 2×5=10 two-dimensional excitation conditions. The navigation echo signals under the two-dimensional excitation conditions are respectively represented by A, B, C, D, E, F, G, H, I, and J. The position of each navigation echo signal corresponds to the position of the solid line of the respiratory monitor waveform.

The two-dimensional excitation condition optimization unit 720 extracts the amplitude of each excitation condition from this result, and sets a value with maximum amplitude to an optimum value. Although it is preferable that the process for obtaining the optimum value is executed by the two-dimensional excitation condition optimization unit 720, the user may designate a desired excitation condition. In this case, the two-dimensional excitation condition optimization unit 720 displays the graph shown in FIG. 8(b) on the display device 73, receives a designation from the user, and sets the designation to an optimum value.

When a diaphragm navigator is applied, two-dimensional excitation can be repeated at an interval of about 50 ms. Accordingly, when the navigation echo signals are acquired under 10 two-dimensional excitation conditions, the navigation echo signal of each two-dimensional excitation condition can be substantially acquired at a frequency of once per second. For example, even if the number K of repetition of all two-dimensional excitation conditions is 10, the result can be obtained within about 10 seconds. Accordingly, a single navigation echo signal is acquired as the monitor scan, and all two-dimensional excitation condition are repeated multiple times to perform the optimization process, thereby reducing the time required until an optimum two-dimensional excitation condition is decided.

As described above, the two-dimensional excitation condition optimization unit 720 of this embodiment can optimize the flip angle FA of the two-dimensional exciting RF pulse 111. In regard to the flip angle FA, the result with highest contrast from among the results obtained by shifting only the flip angle FA while other two-dimensional excitation conditions are the same is decided to be an optimum value. This is because contrast is important between the upper end of the liver and the diaphragm in the diaphragm navigator. In regard to an index which represents the magnitude of contrast, a threshold value may be set in advance, and a determination criterion may be whether or not the result exceeds the threshold value. For example, from among the flip angles FA which exceed the threshold value, the flip angle FA with maximum amplitude when other excitation conditions are shifted is set to an optimum value.

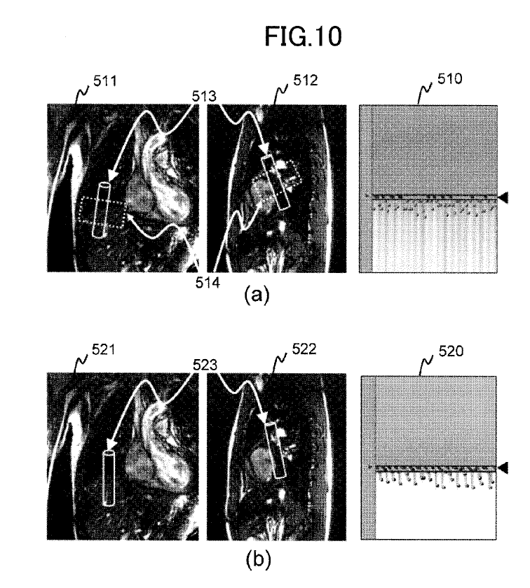

Next, the effects when an application to be applied is a diaphragm navigator and the two-dimensional excitation conditions are optimized to the optimum two-dimensional excitation conditions by the two-dimensional excitation condition optimization process of this embodiment are shown. FIG. 10 shows a two-dimensional excitation position and an acquired respiratory monitor waveform before and after the optimization of this embodiment. FIG. 10(a) shows before optimization, and FIG. 10(b) shows after optimization.

In FIGS. 10(a) and 10(b), coronal images 511 and 521, sagittal images 512 and 522, and respiratory monitor waveforms 510 and 520 are shown from the left of the drawing. The respiratory monitor waveforms 510 and 520 are acquired in two-dimensional excitation regions 513 and 523 shown in cylindrical regions on the images shown on the left sides of the respiratory monitor waveforms.

The two-dimensional excitation region 513 shown in FIG. 10(a) is set by the operator on the positioning image using the method of the related art. The two-dimensional excitation region 523 shown in FIG. 10(b) is the region which is optimized using the method of this embodiment. Here, the two-dimensional excitation region 523 is decided by shifting the center of the two-dimensional excitation region (initial region) 513 in a region 514 indicated by a broken line in FIG. 10(a). After the position L and the slope θ are decided, the flip angle FA is also optimized.

In the example shown in this drawing, after optimization, as to the coronal image 521 and the sagittal image 522, the direction of the center axis of the cylinder of the two-dimensional excitation region 523 becomes close to the boxy axis direction compared to before optimization. In the obtained respiratory monitor waveform 520, contrast of the liver region (the lower side of the waveform) and the lung field (the upper side of the waveform) is improved. Focusing on a data collectable portion indicated by a triangular mark on the right side of each of the respiratory monitor waveforms 510 and 520, it is understood that data is stably collected.

Accordingly, it is shown that the two-dimensional excitation condition optimization process of this embodiment is performed to optimize the two-dimensional excitation conditions to the optimum two-dimensional excitation conditions, whereby image quality is improved.

Next, for example, the flow of the optimization process of Step S1104 will be described as to a case where an application to be applied is a non-contrast MRA.

When two-dimensional excitation is applied to a non-contrast MRA, it is important to apply an excitation pulse only to an intended blood vessel (objective blood vessel), that is, it is important to make the two-dimensional excitation region conform to the objective blood vessel.

Accordingly, in the two-dimensional excitation condition optimization process of this embodiment, the position L and the slope θ of the two-dimensional excitation region are shifted to acquire echo signals, and a two-dimensional excitation condition when an excitation pulse is not applied to other than the objective blood vessel and the two-dimensional excitation region conforms to the objective blood vessel is optimized as an optimum value.

In the non-contrast MRA, if a high-frequency magnetic field of two-dimensional excitation is applied to other than the objective blood vessel, the generation position of an echo signal from a blood flow which is acquired after a predetermined time elapses is plural. This is because change in the generation position of an echo signal which is generated from blood depends on a blood flow rate, and thus echo signals from blood with different blood flow directions or different blood flow rates are generated at different positions. Accordingly, when an echo signal other than the objective blood vessel is included, the generation position of an echo signal is generated is plural.

Specifically, an echo signal is acquired twice at a predetermined time interval under predetermined two-dimensional excitation conditions. While the generation position of an echo signal which is generated from blood changes depending on the blood flow rate and the elapsed time, the generation position of an echo signal which is generated from an internal organ remains unchanged even if the time elapses. For this reason, a differential process and an arithmetic process taking into consideration echo signal attenuation depending on the time interval are applied to both echo signals, and a component in which the generation position of the echo signal does not change is removed. In this way, only echo signals whose generation position changes is extracted, and of these, an echo signal whose generation position is plural is determined. This is repeated while changing the two-dimensional excitation conditions, and a two-dimensional excitation condition when the generation position is singular is decided to be an optimum value.

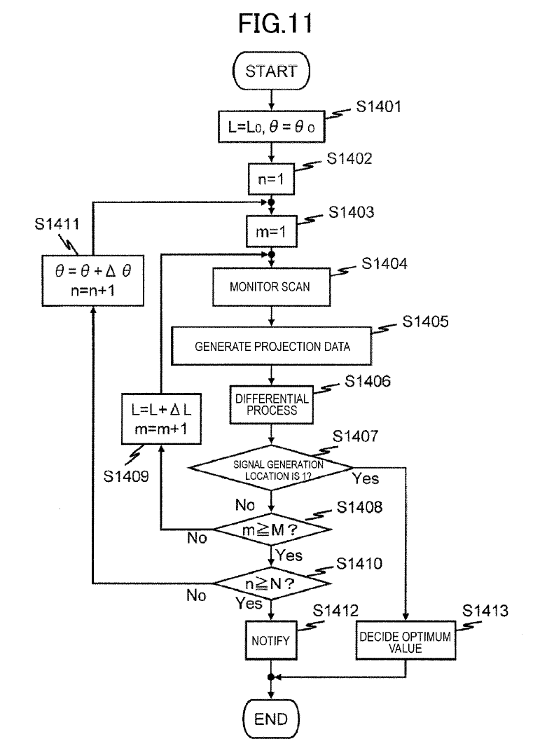

Hereinafter, when an application to be applied is a non-contrast MRA, the optimization process which is executed by the two-dimensional excitation condition optimization unit 720 of this embodiment will be described referring to FIG. 11. Here, for example, a case where parameters to be shifted are the posit nL (x direction Lx, y direction Ly, and z direction Lz) and the slope θ, and designation is made so as to shift the position L (initial position Lx₀, Ly₀, Lz₀) by shift amounts ΔLX, ΔLy, and ΔLz M times (the same number of times in the three directions) and the slope θ (initial value θ₀) by the shift amount Δθ N times will be described. m and n are counters. Here, M and N are integers equal to or greater than 1, and m and n are integers which satisfy 1≦m≦M and 1≦n≦N.

The position L and the slope θ are set to the initial values (Lx₀, Ly₀, Lz₀ (hereinafter, representatively referred to as Lₒ) and θ₀) (Step S1401), and the counter n is set to 1 (Step S1402). The counter m is set to 1 (Step S1403). Then, a monitor scan is executed under the two-dimensional excitation conditions which are obtained from the position (x direction Lx, y direction Ly, and z direction Lz; hereinafter, representatively referred to as L) and the slope θ at this time (Step S1404).

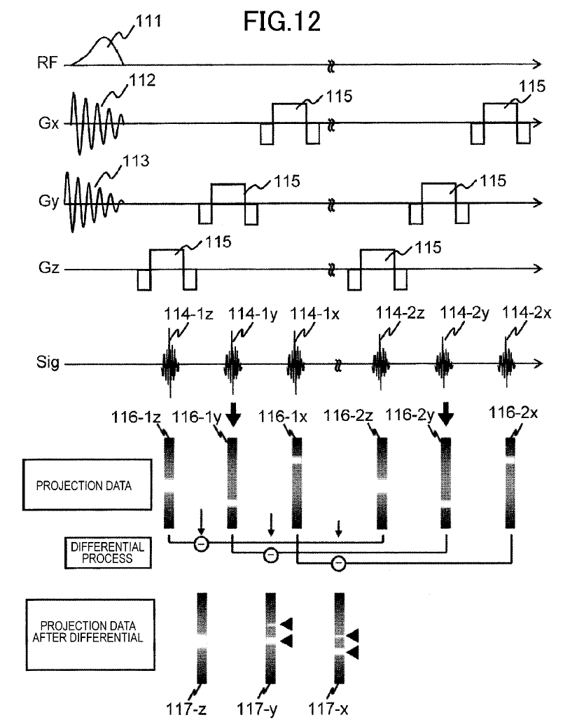

The monitor scan which is executed herein will be described. FIG. 12 is a sequence diagram of a monitor scan which is executed when an application to be applied is a non-contrast MRA. Here, RF which is the axis representing the application timing of the RF pulse and Sig which is the axis representing the echo signal acquisition t g are shown to be separate axes.

As shown in this drawing, here, a first echo signal 114-1 is acquired while applying the lead-out gradient magnetic field 115 immediately after the two-dimensional exciting RF pulse 111 is applied. At this time, an echo signal 114-1P (P is one of x, y, and z) in each direction of x, y, and z is acquired while applying the lead-out gradient magnetic field 115 in each direction. After a predetermined time Δt has elapsed, similarly, a second echo signal 114-2P (P is one of x, y, and z) in each direction of x, y, and z is acquired while applying the lead-out gradient magnetic field 115 in each direction of x, y, and z.

Thereafter, the two-dimensional excitation condition optimization unit 720 generates projection data from the acquired echo signals 114-1P and 114-22 (Step S1405). The generated projection data is shown below the Sig axis. Here, projection data generated from the echo signals 114-1P and 114-22 is shown as 116-1P and 116-2P. In projection data 116-12 and 116-2P shown in this drawing, shading represents signal intensity, and lighter shading represents a higher signal. The vertical axis of projection data corresponds to the position coordinates in the lead-out direction applied when acquiring the echo signal serving as a generation source.

The differential process is performed between projection data 123-1P and projection data 116-2P for each of the x direction, the y direction, and the z direction (Step S1406). The result is shown as projection data 117-P after differential. A high-signal region of the projection data 117-P after differential is obtained by extracting an echo signal whose generation position changes.

The two-dimensional excitation condition optimization unit 720 determines whether or not the generation position of the echo signal is one in all directions on the basis of the number of high-signal regions (Step S1407). At this time, when a plurality of high-signal regions are observed in at least one direction, it is determined that the high-frequency magnetic field of the two-dimensional excitation is applied to other than the objective blood vessel. When the high-signal region is one in all directions, it is determined that the high-frequency magnetic field of the two-dimensional excitation is applied only to the objective blood vessel.

For example, in the example of FIG. 12, a plurality of high-signal regions (black triangles in the drawing) are observed in projection data 117-y and 117-x after differential. Accordingly, echo signals with different blood flow directions or different rates are detected, and it is determined that the high-frequency magnetic field of the two-dimensional excitation is applied to other than the objective blood vessel.

In Step S1407, when one high-signal region is observed in all directions, a two-dimensional excitation condition at this time is decided to be an optimum value (Step S1413), and the process ends.

In Step S1407, when a plurality of high-signal regions are observed in at least one direction, it is determined whether or not the position L is shifted M times using the counter m (Step S1408). If m<M, the position L is shifted by Lx, ΔLy, and ΔLz (hereinafter, representatively referred to as ΔL), and m is incremented by 1 (Step S1409). Then, the process returns to Step S1404, and the monitor scan is repeated.

In Step S1408, if m M, it is determined whether or not the slope θ is shifted N times using the counter n (Step S1410). If n<N, the slope θ is shifted by Δθ, and n is incremented by 1 (Step S1411). Then, the process returns to Step S1403, and the monitor scan is repeated.

In Step S1410, if n≧N, the two-dimensional excitation condition optimization unit 720 generates a message to the effect that it is not possible to set the optimum excitation conditions with a designated shift count, notifies the operator of the message (Step S1412), and ends the process. At this time, the excitation conditions may be decided with reference to a database described below.

Although the number of echo signals which are acquired as the first echo signal and the second echo signal is not limited, it is desirable that the echo signal is acquired at least once in the three directions of the x direction, the y direction, and the z direction while applying the lead-out gradient magnetic field. Although the time interval Δt for which the first echo signal 114-1P and the second echo signal 114-2P are collected depends on the blood flow rate in the target blood vessel, it is desirable that the time interval Δt is about several 100 ms.

When an application to be applied is a non-contrast MRA, a configuration may be made such that the setting of the shift count is not performed on the shift condition setting screen 200. In this case, the process is repeated until the high-signal region is singular.

Although it is desirable that the number of generation positions of the echo signal is determined by the two-dimensional excitation condition optimization unit 720, the user may determine the number of generation positions of the echo signal. In this case, in Step S1407, the two-dimensional excitation condition optimization unit 720 displays projection data after differential shown in FIG. 12 on the display device 73, receives an instruction of whether the generation position is one from the user, and continues the process.

As described above, according to this embodiment, it is possible to automatically optimize the two-dimensional excitation conditions of the two-dimensional excitation using the pre-pulse to the optimum values in accordance with the subsequent main imaging sequence. Accordingly, since the two-dimensional excitation is executed using the two-dimensional excitation conditions after optimization, it is possible to excite an accurate position according to the purpose of the subsequent main imaging sequence. Therefore, image quality of an image to be obtained is improved.

In this embodiment, the two-dimensional excitation conditions after optimization are displayed on the positioning image. Therefore, the operator can view the two-dimensional excitation region after optimization.

The navigation echo signals (respiratory monitor waveforms) or projection data after differential for the respective two-dimensional excitation conditions collected by the optimization process may be stored in the storage device 72 as a database in association with the two-dimensional excitation conditions.

At this time, each time the operator moves the UI of the two-dimensional excitation on the positioning image, the control processing system 70 may display, on the display device 73, the navigation echo signal (respiratory monitor waveform) or projection data after differential which is stored in the database in association with a two-dimensional excitation condition closest to a two-dimensional excitation condition specified by the UI after movement. With this configuration, even if the two-dimensional excitation condition optimization process is not performed every time, since the respiratory monitor waveform or projection data after differential can be displayed, the operator can decide the optimum two-dimensional excitation conditions.

In the two-dimensional excitation condition optimization process, the initial value of each two-dimensional excitation condition may be defined in advance and stored in the storage device 72.

The number of changes and the shift amount of each excitation condition may be defined in advance and stored in the storage device 72.

As described above, the two-dimensional excitation has a limited excitation region compared to general planar excitation. The two-dimensional excitation conditions are optimized to the optimum values using the method of this embodiment, whereby a desired region can be exceeded with high precision. With this, after the two-dimensional excitation conditions of the two-dimensional excitation are optimized by the above-described method, the parameters of the subsequent main imaging sequence may be optimized using the two-dimensional excitation. In this case, the control processing system 70 of this embodiment includes an imaging condition optimization unit which optimizes the parameters of the main imaging sequence to optimum values.

Hereinafter, for example, as to a case where an application to be applied is a non-contrast MRA, a process (imaging condition optimization process) for optimizing the parameters of the main imaging sequence by the imaging condition optimization unit of this embodiment will be described.

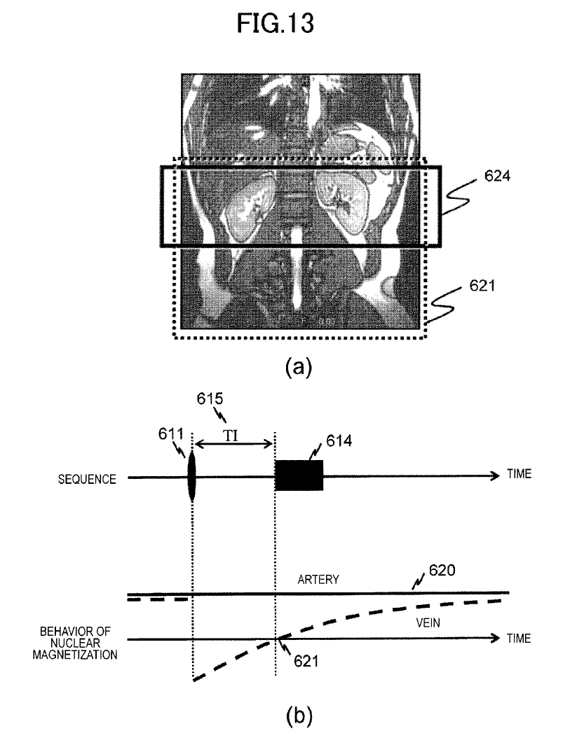

Prior to describing the imaging condition optimization process, an imaging position, a pulse sequence, and behavior of nuclear magnetization in a typical non-contrast MRA will be described. FIG. 13(a) is a diagram illustrating an imaging position, and FIG. 13(b) is a diagram illustrating a pulse sequence and behavior of nuclear magnetization.

In the non-contrast MRA, for example, as a method which images an artery, the following methods are used.
a method which selectively images a signal of an artery
a method which performs differential between an image of an artery and a vein and an image of only a vein, and images an artery

In regard to a blood vessel to be imaged, the number of times of the application of the pre-pulse, the region, and the application timing, various variations are considered. Accordingly, the following description is merely a typical application example, and this embodiment is not limited to the following description.

As shown in FIG. 13(b), in the non-contrast MRA, main imaging sequence is executed when the standby time TI 615 of about one second elapses after the application of an inversion pulse (space selection 180 deg. pulse) 611, and an echo signal for use in image creation is acquired (data collection 614). The application region of the inversion pulse 611 is a region 621 of FIG. 13(a), and a region where data is collected is a region 624 of FIG. 13(a). In the main imaging sequence, a measurement sequence, such as fast spin echo or SSFP-type gradient echo, is used.

At this time, as shown in the behavior 620 of nuclear magnetization, as the standby time TI 615, the timing (null time) 621 at which signal intensity of a part whose signal should be suppressed or an internal organ (in this case, vein) is zero on an image is introduced. The standby time TI 615 conforms to the null time with high precision, whereby a signal from an unwanted part or the like can be suppressed and image quality is improved.

When a pre-pulse is two-dimensional excitation, since the excitation region is limited, the setting of a slab thickness S should be decided taking into consideration the standby time TI and the blood flow rate V.

Ina present situation, the standby time TI and the slab thickness S are decided by executing the main imaging sequence under the condition in which resolution is lower than an echo signal for image reconstruction. Alternatively, a dedicated sequence which measures the standby time TI or the blood flow rate is executed and the standby time TI or the blood flow rate is decided from the result. Accordingly, in any cases, in order to decide an optimum value, since a two-dimensional or three-dimensional image is acquired while changing the standby time TI, it takes a lot of time.

An imaging condition optimization unit executes a sequence defined in advance and processes the result obtained along with an algorithm defined in advance, thereby automatically deciding the optimum standby time TI and slab thickness S at a high speed. Hereinafter, a procedure for deciding the standby time TI and the slab thickness S by the imaging condition optimization unit will be described. As described above, the slab thickness S is decided by the standby time TI and the blood flow rate V. Accordingly, here, a procedure for deciding the standby time TI and the blood flow rate V will be described. It is assumed that the two-dimensional excitation conditions of the two-dimensional excitation to be applied as the pre-pulse are optimized to the optimum values by the above-described method.

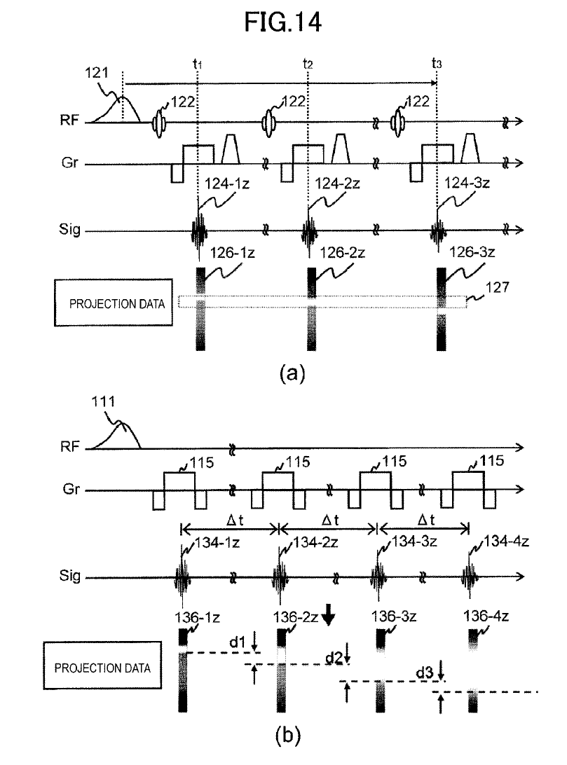

FIG. 14 is a sequence diagram which is executed by the imaging condition optimization unit of this embodiment. FIG. 14(a) shows an example of a sequence which is executed when calculating the relaxation time TI and the standby time TI of blood, and FIG. 14(b) shows an example of a sequence which is executed when calculating the blood flow rate V. Here, the gradient magnetic field of the two-dimensional excitation sequence is omitted, and the gradient magnetic fields in the respective directions during data collection are collectively shown using a vector r. In regard to the echo signals, the echo signals which are collected by applying the lead-out gradient magnetic field in the z direction are representatively shown.

It is desirable that the number of echo signals to be collected is at least three or more with the lead-out gradient magnetic field applied in the three orthogonal directions during collection.

First, a method of calculating the relaxation time T1 of blood and the standby time TI by the imaging condition optimization unit will be described. As shown in FIG. 14(a), first, a high-frequency magnetic field (inversion pulse; 180 deg.) 121 is applied to an intended blood vessel by the two-dimensional excitation, and nuclear magnetization is inverted at 180 deg. Thereafter, echo signals 124-nz (where n is an integer which represents an echo generation order) are generated at a predetermined time interval Δt using a gradient echo method or the like which uses a low-FA (α deg.) RF pulse 122.

As will be generally known, nuclear magnetization attenuation by the vertical relaxation is reflected in the intensity of the echo signal after 180 deg. inversion. Here, with this, the transition of the intensity of the echo signals acquired at a given time interval is parameter-fitted to a relaxation expression, and the vertical relaxation time TI of blood is calculated.

Specifically, the imaging condition optimization unit acquires the echo signals 124-nz generated at a given time interval Δt, applies a one-dimensional Fourier transform to each acquired echo signal 124-nz, and obtains projection data 126-nz. The vertical axis of projection data 126-nz corresponds to the position coordinates in the lead-out direction applied when acquiring the echo signal serving as a generation source. Accordingly, the signal intensity of blood at a position 127 corresponding to an objective part of projection data 126-nz is extracted and set to the signal intensity for each elapsed time tn of the echo signal acquisition timing of the generation source from the inversion pulse 121. The signal intensity and the elapsed time tn are parameter-fitted to the relaxation expression to decide the vertical relaxation time T1. The null time of blood is calculated using the decided vertical relaxation time T1. The calculated null time is set to the standby time TI.

Next, a method of calculating the blood flow rate V by the imaging condition optimization unit will be described. A sequence shown in FIG. 14(b) which is executed at this time is substantially the same as the sequence shown in FIG. 12. That is, the acquisition of an echo signal 134-nz (where n is an integer which represents an echo generation order) at a predetermined time interval Δt after the application of the two-dimensional exciting RF pulse 111 is repeated. Although the time interval of the echo signal acquisition depends on the blood flow rate V, it is desirable that the time interval of the echo signal acquisition is about 100 to 200 ms.

Projection data 136-nz is generated from each acquired echo signal 134-nz. The travel distances d1 to d3 for each time interval Δt are detected using a high-signal region of the generated projection data 136-nz, and the blood flow rate V is calculated.

The standby time TI and the blood flow rate V are calculated by the above-described method, and the product of the standby time TI and the blood flow rate is set to an indication of the slab thickness S.

As described above, according to the imaging condition optimization process by the imaging condition optimization unit, the parameters of the main imaging sequence when two-dimensional excitation is used in a pre-pulse can be optimized to the optimum values.

Here, for example, although a case where the standby time TI and the slab thickness S are decided has been described, the parameters which can be adjusted using the two-dimensional excitation are not limited thereto. Parameters related to contrast of blood and surrounding tissues and the length of a blood vessel to be extracted may be used. For example, the number of echo signals which are acquired by a divided measurement of one degree (for example, for each heart beat or for each respiratory cycle) may be used. For example, the number of echo signals is et to the number of echo signals which can be acquired within a predefined proportion (for example, 0 to 15%) of a threshold value to intensity before inversion pulse application on the basis of the decided vertical relaxation T1 of the blood signal.

This embodiment has been described as to a case where an application to be applied is a respiratory monitor by a diaphragm navigator and a non-contrast MRA. These are representative examples, and various developments are possible. That is, in the optimization step, the items to be evaluated and the determination criterion for optimization may be designated according to the purpose.

The invention is not limited to a single application to be applied. For example, a respiratory monitor using a diaphragm navigator and a non-contrast MRA may be used in combination. It is assumed that optimization to the optimum value is performed at each position in accordance with the above-described procedure for optimizing the two-dimensional excitation conditions when each of a diaphragm navigator and a non-contrast MRA is an application to be applied. When the imaging target of the non-contrast MRA is away from the diaphragm, it is preferable that the position of the two-dimensional excitation in the diaphragm navigator is the abdominal wall.

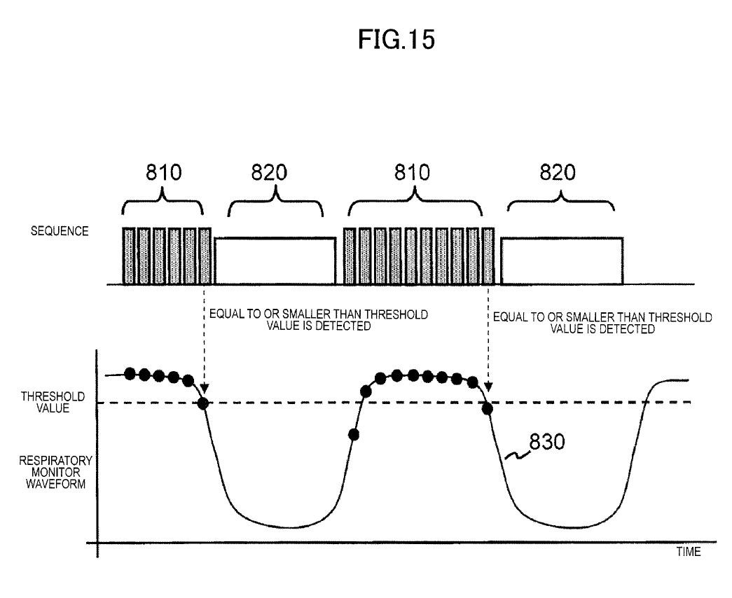

As described above, the relationship between the execution procedure of both sequences after the optimization of the two-dimensional excitation conditions of the two-dimensional excitation and the respiratory monitor waveform when the diaphragm navigator and the non-contrast MRA are used in combination is shown in FIG. 15. Although a respiratory monitor waveform 830 shown on the lower side intrinsically has a waveform indicated by a solid line, since it is not possible to monitor the respiration using the diaphragm navigator while the non-contrast MRA sequence is being executed, sampling points of this waveform are limited to data points indicated by black circles on the solid line. Accordingly, the waveform during the execution of the non-contrast MRA sequence is an estimated waveform.

First, a diaphragm navigator 810 is executed at an interval of several 100 ms to detect the position of the diaphragm. When the detected position is equal to or smaller than a threshold value designated by the respiratory monitor waveform 830 and low compared to the last detected diaphragm position, a non-contrast MRA sequence 820 is executed.

The reason for comparison with the last detected diaphragm position is to distinguish between the transition from expiration to inspiration and the transition from inspiration to expiration. Immediately after data acquisition in the non-contrast MRA sequence 820 ends, the diaphragm navigator 810 is executed.

As described above, a respiratory monitor using a diaphragm navigator and a non-contrast MRA can be used in combination. This embodiment can be applied as two-dimensional excitation optimizing method in various applications which use two-dimensional excitation, and is not limited to the applications described in this embodiment.

As will be apparent from the above description of the embodiment of the invention, the features of the invention are arranged as follows.

That is, the MRI apparatus of the invention includes an imaging unit which images a desired region of an inspection target arranged in a static magnetic field by nuclear magnetic resonance, and a control unit which controls the imaging unit in accordance with a predefined imaging sequence and performs an arithmetic process, wherein the control unit includes an excitation condition optimization unit which optimizes excitation conditions of a two-dimensional excitation sequence exciting an imaging space in a columnar shape, and the imaging unit executes the two-dimensional excitation sequence under the excitation conditions optimized by the excitation condition optimization unit.

Preferably, the excitation condition optimization unit excites the imaging space in a cylindrical shape, an elliptic cylindrical shape, or a prismatic shape and optimizes initial excitation conditions for the excitation in accordance with an application to which the two-dimensional excitation sequence is applied.

Preferably, the excitation condition optimization unit repeats a monitor scan of the application to be applied while shifting a parameter value to be optimized from among the excitation conditions, and sets an optimum value, which is a parameter value when a result conforming to predefined conditions is obtained, to the parameter value, whereby optimization is performed.

Preferably, the application to be applied is a diaphragm navigator, and the excitation condition optimization unit executes the monitor scan while shifting the parameter value to be optimized, and sets a parameter value, for which a region where position fluctuation is maximal as the result of the monitor scan is the two-dimensional excitation region, to the optimum value.

Preferably, the monitor scan is a sequence which collects echo signals between a plurality of respiratory cycles under the same excitation conditions, and the excitation condition optimization unit sets, to the optimum value, a parameter value under excitation conditions when the range of fluctuation of the echo signals in the plurality of respiratory periods is maximal.

Preferably, the monitor scan is a sequence which collects a single echo signal under the same excitation conditions, and the excitation condition optimization unit repeatedly executes the monitor scan while shifting the parameter value to be optimized a predefined number of times, and sets an excitation condition, in which the range of fluctuation between the results obtained under the same excitation conditions is maximal, to the optimum value.

Preferably, the application to be applied is a non-contrast MRA, and the excitation condition optimization unit executes a monitor scan while shifting the parameter value to be optimized, and sets a parameter value, for which a two-dimensional excitation region conforms to an objective blood vessel, to the optimum value.

Preferably, the monitor scan acquires two echo signals at different times, and the excitation condition optimization unit performs a differential process on the two acquired echo signals, and when the number of generation positions of the echo signals is singular, and determines that two echo signals conform to each other.

Preferably, the parameter to be optimized is at least one of the position, diameter, and slope of the two-dimensional excitation region, and a flip angle of a two-dimensional exciting RP pulse to be applied by the two-dimensional excitation sequence.

Preferably, the magnetic resonance imaging apparatus further includes a reception unit which receives input of the application to be applied, the parameter to be optimized, and change conditions from an operator.

Preferably, the magnetic resonance imaging apparatus further includes an imaging condition optimization unit which optimizes imaging conditions of a main imaging sequence to be executed after the two-dimensional excitation sequence, wherein the imaging condition optimization unit optimizes the imaging conditions using the two-dimensional excitation after the optimization by the excitation condition optimization unit.

Preferably, the magnetic resonance imaging apparatus further includes an imaging condition optimization unit which optimizes imaging conditions of a main imaging sequence to be executed after the two-dimensional excitation sequence, wherein the imaging conditions to be optimized include an inversion time, and the imaging condition optimization unit decides an optimum inversion time from echo signals acquired at a predetermined time interval after nuclear magnetization is inversed by the two-dimensional excitation sequence subsequent to the optimization.

Preferably, the imaging conditions to be optimized further include a slab thickness, and the imaging condition optimization unit calculates a blood flow rate from a plurality of echo signals acquired at a predetermined time intervals after executing the two-dimensional excitation sequence subsequent to the optimization, and decides an optimum slab thickness from the blood flow rate and the inversion time.

An imaging parameter optimizing method in an MRI apparatus of the invention includes an excitation condition optimization step of optimizing excitation conditions of a two-dimensional excitation sequence exciting an imaging space in a columnar shape in accordance with an application to be applied.

Preferably, in the excitation condition optimization step, the imaging space is excited in a cylindrical shape, an elliptic cylindrical shape, or a prismatic shape, and the imaging parameter optimizing method further includes, after the excitation condition optimization step, an imaging condition optimization step of optimizing imaging parameters of a main imaging sequence to be executed after the two-dimensional excitation sequence.

### REFERENCE SIGNS LIST

10: MRI apparatus, 11: object, 20: static magnetic field generation system, 30: gradient magnetic field generation system, 31: gradient magnetic field coil, 32: gradient magnetic field power supply, 40: sequencer, 50: transmission system, 51: transmission coil, 52: synthesizer, 53: modulator, 54: high-frequency amplifier, 60: reception system, 61: reception coil, 62: signal amplifier, 63: quadrature phase detector, 64: A/D converter, 70: control processing system, 71: CPU, 72: storage device, 73: display device, 74: input device, 101: two-dimensional excitation region, 102: imaging target, 110: two-dimensional excitation sequence, 111: two-dimensional exciting RF pulse, 112: vibration gradient magnetic field Gx, 113: vibration gradient magnetic field Gy, 114: echo signal, 115: lead-out gradient magnetic field Gz, 116: projection data, 117: differential projection data, 121: inversion pulse, 122: low-FA RFpulse, 124: echo signal, 126: projection data, 134: echo signal, 136: projection data, 200: shift condition setting screen, 210: adjustment target designation region, 220: shift count input region, 230: shift amount input region, 240: optimization mode setting region, 311: diaphragm, 312: heart, 313: liver, 320: two-dimensional excitation region, 330: respiratory monitor waveform, 331: amplitude, 332: lower limit, 333: upper limit, 410: graph, 410A: graph, 410B: graph, 410C: graph, 410D: graph, 420: graph, 510: respiratory monitor waveform, 511: coronal image, 512: sagittal image, 513: two-dimensional excitation region, 514: region, 520: respiratory monitor waveform, 521: coronal image, 522: sagittal image, 523: two-dimensional excitation region, 611: inversion pulse, 614: data collection, 615: TI, 621: region, 624: region, 710: imaging unit, 720: two-dimensional excitation condition optimization unit, 730: shift condition reception unit, 810: diaphragm navigator, 820: non-contrast MRA, 830: respiratory monitor waveform

1. A magnetic resonance imaging apparatus comprising:
an imaging unit which images a desired region of an inspection target arranged in a static magnetic field by nuclear magnetic resonance; and
a control unit which controls the imaging unit in accordance with a predefined imaging sequence and performs an arithmetic process,
wherein the control unit includes an excitation condition optimization unit which optimizes excitation conditions of a two-dimensional excitation sequence exciting an imaging space in a columnar shape, and
the imaging unit executes the two-dimensional excitation sequence under the excitation conditions optimized by the excitation condition optimization unit.

2. The magnetic resonance imaging apparatus according to claim 1,
wherein the excitation condition optimization unit excites the imaging space in a cylindrical shape, an elliptic cylindrical shape, or a prismatic shape and optimizes initial excitation conditions for the excitation in accordance with an application to which the two-dimensional excitation sequence is applied.

3. The magnetic resonance imaging apparatus according to claim 2,
wherein the excitation condition optimization unit repeats a monitor scan of the application to be applied while shifting a parameter value to be optimized from among the excitation conditions, and sets an optimum value, which is a parameter value when a result conforming to predefined conditions is obtained, to the parameter value whereby optimization is performed.

4. The magnetic resonance imaging apparatus according to claim 3,
wherein the application to be applied is a diaphragm navigator, and
the excitation condition optimization unit executes the monitor scan while shifting the parameter value to be optimized, and sets a parameter value, for which a region where position fluctuation is maximal as the result of the monitor scan is the region of the two-dimensional excitation, to the optimum value.

5. The magnetic resonance imaging apparatus according to claim 4,
wherein the monitor scan is a sequence which collects echo signals between a plurality of respiratory cycles under the same excitation conditions, and
the excitation condition optimization unit sets, to the optimum value, a parameter value under excitation conditions when the range of fluctuation of the echo signals in the plurality of respiratory cycles is maximal.

6. The magnetic resonance imaging apparatus according to claim 4,
wherein the monitor scan is a sequence which collects a single echo signal under the same excitation conditions, and
the excitation condition optimization unit repeatedly executes the monitor scan while shifting the parameter value to be optimized a predefined number of times, and sets an excitation condition, in which the range of fluctuation between the results obtained under the same excitation conditions is maximal, to the optimum value.

7. The magnetic resonance imaging apparatus according to claim 3,
wherein the application to be applied is a non-contrast MRA, and
the excitation condition optimization unit executes a monitor scan while shifting the parameter value to be optimized, and sets a parameter value, for which a two-dimensional excitation region conforms to an objective blood vessel, to the optimum value.

8. The magnetic resonance imaging apparatus according to claim 7,
wherein the monitor scan acquires two echo signals at different times, and
the excitation condition optimization unit performs a differential process on the two acquired echo signals, and when the number of generation positions of the echo signals is singular, and determines that two echo signals conform to each other.

9. The magnetic resonance imaging apparatus according to claim 3,
wherein the parameter to be optimized is at least one of the position, diameter, and slope of the two-dimensional excitation region, and a flip angle of a two-dimensional exciting RF pulse to be applied by the two-dimensional excitation sequence.

10. The magnetic resonance imaging apparatus according to claim 3, further comprising:
a reception unit which receives input of the application to be applied, the parameter to be optimized, and change conditions from an operator.

11. The magnetic resonance imaging apparatus according to claim 3, further comprising:
an imaging condition optimization unit which optimizes imaging conditions of a main imaging sequence to be executed after the two-dimensional excitation sequence,
wherein the imaging condition optimization unit optimizes the imaging conditions using the two-dimensional excitation after the optimization by the excitation condition optimization unit.

12. The magnetic resonance imaging apparatus according to claim 7, further comprising:
an imaging condition optimization unit which optimizes imaging conditions of a main imaging sequence to be executed after the two-dimensional excitation sequence,
wherein the imaging conditions to be optimized include an inversion time, and
the imaging condition optimization unit decides an optimum inversion time from echo signals acquired at a predetermined time interval after nuclear magnetization is inversed by the two-dimensional excitation sequence subsequent to the optimization.

13. The magnetic resonance imaging apparatus according to claim 12,
wherein the imaging conditions to be optimized further include a slab thickness, and
the imaging condition optimization unit calculates a blood flow rate from a plurality of echo signals acquired at a predetermined time intervals after executing the two-dimensional excitation sequence subsequent to the optimization, and decides an optimum slab thickness from the blood flow rate and the inversion time.

14. An imaging parameter optimizing method in a magnetic resonance imaging apparatus, the imaging parameter optimizing method comprising:
an excitation condition optimization step of optimizing excitation conditions of a two-dimensional excitation sequence exciting an imaging space in a columnar shape in accordance with an application to be applied.

15. The imaging parameter optimizing method according to claim 14,
wherein, in the excitation condition optimization step, the imaging space is excited in a cylindrical shape, an elliptic cylindrical shape, or a prismatic shape, and
the imaging parameter optimizing method further comprises, after the excitation condition optimization step, an imaging condition optimization step of optimizing imaging parameters of a main imaging sequence to be executed after the two-dimensional excitation sequence.
